(19) United States
(12) Patent Application Publication
(10) Pub. No.: US 2013/0087896 A1
(43) Pub. Date: Apr. 11, 2013

(54) STACKING-TYPE SEMICONDUCTOR PACKAGE STRUCTURE

(71) Applicant: Ju-Tsung CHOU, New Taipei City (TW)

(72) Inventor: Ju-Tsung CHOU, New Taipei City (TW)

(21) Appl. No.: 13/331,294

(22) Filed: Dec. 20, 2011

(30) Foreign Application Priority Data
Oct. 5, 2011 (TW) 100136082

(51) Int. Cl. H01L 23/552; H01L 23/498

(52) U.S. Cl. 257/659; 257/738; 257/E23.069; 257/E23.114

(57) ABSTRACT

A stacking-type semiconductor package structure includes a first package body, multiple first connecting conductors, a second package body, multiple second connecting conductors, an electronic function module, and multiple third connecting conductors. The first connecting conductors are disposed on a lower surface of the first package body and connected electrically to the first package body. The second package body and the electronic function module are disposed on an upper surface of the first package body. The second connecting conductors are connected electrically between the first package body and the second package body, and the third connecting conductors are connected electrically between the first package body and the electronic function module. The second package body has an electronic function different from that of the electronic function module.

### CROSS-REFERENCES TO RELATED APPLICATIONS

This non-provisional application claims priority under 35 U.S.C. §119(a) on Patent Application No. 100136082 filed in Taiwan, R.O.C. on Oct. 5, 2011, the entire contents of which are hereby incorporated by reference.

### BACKGROUND OF THE INVENTION

1. Technical Field

The present invention relates to a package structure, and more particularly to a stacking-type semiconductor package structure.

2. Related Art

As electronic products become increasingly short, small, light and thin, their circuit boards also become smaller, resulting in an area for disposing elements on the circuit board being reduced accordingly. Consequently, it is becoming increasingly difficult to implement the conventional manner of directly jointing multiple chips to the circuit board side-by-side, in advanced miniature electronic products. A device in which multiple chips are stacked vertically, namely semiconductor Package-On-Package (POP) device, is therefore developed. Here, different chips are stacked and integrated on the same substrate through a Surface Mount Technology (SMT), so as to meet requirements of small jointing area and high element disposition density.

Furthermore, with rapidly increasing requirements for functions and applications of the electronic products, many advanced package technologies have been developed, for example: flip-chip, Chip Scale Package (CSP), Wafer Level Package (WLP), and three-dimensional (3D) package.

Current 3D package technology can integrate chips and passive elements into one package body, and may become a solution to System In Package (SIP); 3D package technology may combine multiple chips in a side-by-side manner, a stacking manner or the both of these two manners. A 3D package has the advantages of small footprint area, high performance, and low cost.

Consequently, a method of using the 3D package technology to effectively form a package structure having multiple electronic functions has become a key design point of the current package structure.

### SUMMARY

In an embodiment, a stacking-type semiconductor package structure includes a first package body, multiple first connecting conductors, a second package body, multiple second connecting conductors, an electronic function module, and multiple third connecting conductors.

The first package body includes a first circuit board, at least one first chip, and a first sealing compound. The first chip is located on an upper surface of the first circuit board and connected electrically to the first circuit board. The first sealing compound is located on the upper surface of the first circuit board to envelope the first chip. The first connecting conductors are located on a lower surface of the first circuit board and connected electrically to the first circuit board:

The second package body includes a second circuit board, at least one second chip, and a second sealing compound. The second circuit board is located on the first sealing compound. The second chip is located on an upper surface of the second circuit board and connected electrically to the second circuit board. The second sealing compound is located on the upper surface of the second circuit board to envelope the second chip. The second connecting conductors are located between the first circuit board and the second circuit board, and connected electrically to the first circuit board and the second circuit board.

The electronic function module includes a third circuit board and at least one third chip. The third circuit board is located on the first sealing compound. The third chip is located on an upper surface of the third circuit board and connected electrically to the third circuit board. The third connecting conductors are located between the first circuit board and the third circuit board, and connected electrically to the first circuit board and the third circuit board.

The second package body has an electronic function different from that of the electronic function module.

In conclusion, the stacking-type semiconductor package structure according to the present invention can combine at least three electronic function modules, and the electronic function modules have at least two different electronic functions. Furthermore, the electronic function modules may be assembled separately, and then different electronic function modules assembled, so as to increase yield.

In some embodiments, the stacking-type semiconductor package structure according to the present invention may use gap disposition or configuration of grounding conductors between electronic function modules with different electronic functions, so as to improve the heat dissipation effect.

In some embodiments, the stacking-type semiconductor package structure according to the present invention may use an electromagnetic shielding case to shield electromagnetic waves generated by a wireless communication module, so as to prevent interference with other electronic function modules.

### BRIEF DESCRIPTION OF THE DRAWINGS

FIG. 1 is a top view of a stacking-type semiconductor package structure according to an embodiment of the present invention;

FIG. 2 is a schematic view of a section structure along a tangential line A-A′ in FIG. 1 according to an embodiment;

FIG. 3 is an exploded view of a section structure of FIG. 2 according to an embodiment;

FIG. 4A is a top view along a tangential line B-B′ in FIG. 3;

FIG. 4B is a bottom view along a tangential line C-C′ in FIG. 3;

FIG. 5 is an exploded view of a section structure of FIG. 2A according to another embodiment;

FIG. 6A is a top view along a tangential line D-D′ in FIG. 5;

FIG. 6B is a bottom view along a tangential line E-E′ in FIG. 5;

FIG. 7 is a schematic view of a section structure along a tangential line A-A′ in FIG. 1 according to another embodiment;

FIG. 8 is a schematic view of a section structure along a tangential line A-A′ in FIG. 1 according to further another embodiment;

FIG. 9 is a schematic view of a section structure along a tangential line A-A′ in FIG. 1 according to still another embodiment; and

FIG. 10 is a bottom view of a stacking-type semiconductor package structure according to an embodiment of the present invention.

### DETAILED DESCRIPTION

The following terms of first, second, and third are used to distinguish the elements referred, and are not intended for sequencing, or limiting the difference of the elements referred or the scope of the present invention. The following term of circuit board at least includes a single layer or multi-layer substrate and at least one conductive circuit. The conductive circuit is formed on an external surface and/or a surface of an internal interlayer of the substrate. Furthermore, the conductive circuit may penetrate one or more layers of the substrate, so that different surfaces of the substrate are connected electrically.

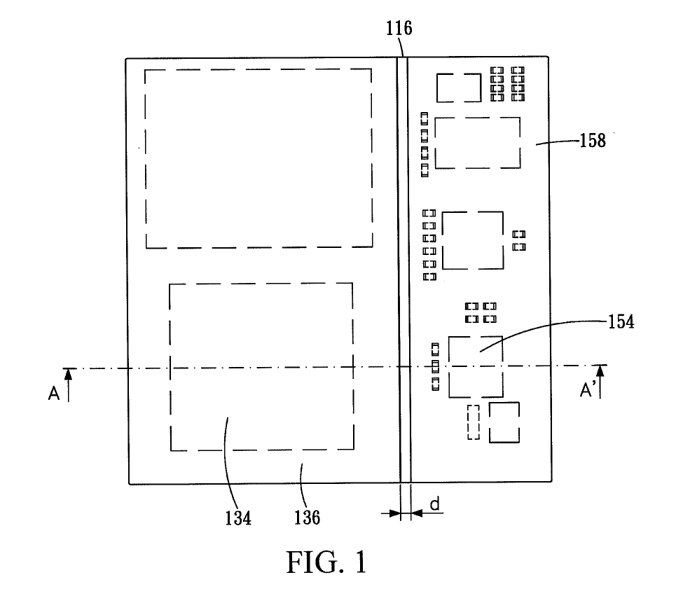

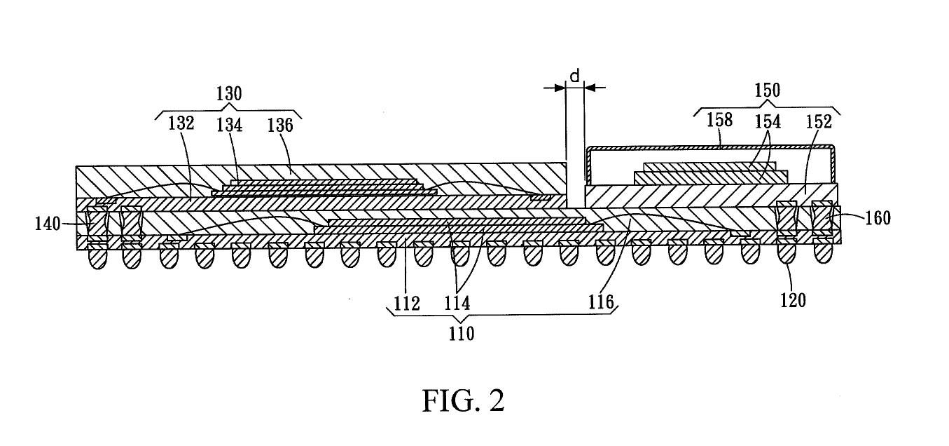

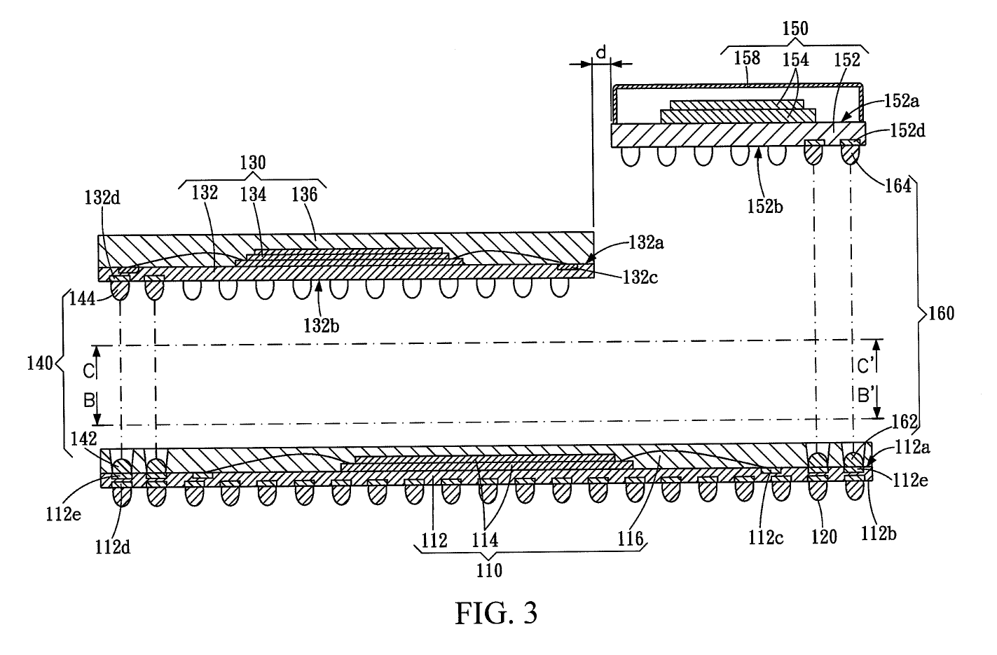

FIG. 1 is a top view of a stacking-type semiconductor package structure according to an embodiment of the present invention; FIG. 2 is a schematic view of a section structure along a tangential line A-A′ in FIG. 1; and FIG. 3 is an exploded view of a section structure of FIG. 2 according to an embodiment.

Please refer to FIG. 1, FIG. 2, and FIG. 3, in which the stacking-type semiconductor package structure includes a first package body 110, multiple first connecting conductors 120, a second package body 130, multiple second connecting conductors 140, an electronic function module 150, and multiple third connecting conductors 160.

Here, the first package body 110, the second package body 130, and the electronic function module 150 may have respective electronic functions. In other words, electronic components (such as a chip, a resistor, a capacitor, an inductor, other active or passive elements, or a combination thereof), disposed in the first package body 110 may run in coordination to execute a specific electronic function, so that the first package body 110 runs as an electronic function module. Electronic components (such as a chip, a resistor, a capacitor, an inductor, other active or passive elements, or a combination thereof), disposed in the second package body 130 may run in coordination to execute a specific electronic function, so that the second package body 130 runs as an electronic function module. Electronic components (such as a chip, a resistor, a capacitor, an inductor, other active or passive elements, or a combination thereof), disposed in the electronic function module 150 may run in coordination to execute a specific electronic function.

The first package body 110 includes a first circuit board 112, at least one first chip 114, and a first sealing compound 116.

The first chip 114 is located on an upper surface 112a of the first circuit board 112 and connected electrically to the first circuit board 112.

In some embodiments, when the first package body 110 has multiple first chips 114, the first chips 114 may be disposed on the upper surface 112a of the first circuit board 112 in a side-by-side manner or stacking manner. In addition, a part of the first chips 114 may be disposed on the upper surface 112a of the first circuit board 112 in a side-by-side manner, and another part is disposed on the upper surface 112a of the first circuit board 112 in a stacking manner.

In some embodiments, the first chip 114 may be connected electrically to the first circuit board 112 through wire-bonding or flip-chip.

The first sealing compound 116 is located on the upper surface 112a of the first circuit board 112. The first sealing compound 116 envelopes the first chip 114, so as to fix the first chip 114 on the first circuit board 112. In other words, the first sealing compound 116 may cover the first chip 114 and the first circuit board 112, so as to wrap the first chip 114 on the first circuit board 112.

The first connecting conductors 120 are arranged on a lower surface 112b of the first circuit board 112 and connected electrically to the first circuit board 112.

Consequently, the electronic components disposed in the first package body 116 may be conducted electrically to the first connecting conductors 120 through the first circuit board 112.

In some embodiments, the upper surface 112a of the first circuit board 112 has multiple interconnecting members 112c. Here, the first chip 114 may be connected electrically to the interconnecting members 112c.

In some embodiments, the interconnecting member 112c may be a contact point on a conductive circuit or a solder pad of the first circuit board 112.

The first circuit board 112 may be a multi-layer circuit board. At least one conductive circuit is arranged on a surface and/or a surface of an internal interlayer of the multi-layer circuit board.

In addition, the interconnecting member 112c may be connected electrically to the first connecting conductors 120 on the lower surface 112b of the first circuit board 112 through the conductive circuit, so that the first chip 114 and the first connecting conductors 120 are conducted electrically.

In some embodiments, the lower surface 112b of the first circuit board 112 may have multiple solder pads 112d. The first connecting conductors 120 are physically connected to the solder pads 112d of the first circuit board 112. In addition, the solder pads 112d are connected electrically to the conductive circuit of the first circuit board 112. Consequently, the first chip 114 on the upper surface 112a may be connected electrically to the first connecting conductors 120 on the lower surface 112b through the conductive circuit and the solder pads 112d.

The second package body 130 includes a second circuit board 132, at least one second chip 134, and a second sealing compound 136.

The second chip 134 is located on an upper surface 132a of the second circuit board 132 and is connected electrically to the second circuit board 132.

In some embodiments, when the second package body 130 has multiple second chips 134, the second chips 134 may be disposed on the upper surface 132a of the second circuit board 132 in a side-by-side manner or stacking manner. In addition, a part of the second chips 134 may be disposed on the upper surface 132a of the second circuit board 132 in a side-by-side manner, and another part is disposed on the upper surface 132a of the second circuit board 132 in a stacking manner.

In some embodiments, the second chip 134 may be connected electrically to the second circuit board 132 through wire-bonding or flip-chip.

The second sealing compound 136 is located on the upper surface 132a of the second circuit board 132. The second sealing compound 136 envelopes the second chip 134, so as to fix the second chip 134 on the second circuit board 132. In other words, the second sealing compound 136 may cover the second chip 134 and the second circuit board 132, so as to wrap the second chip 134 on the second circuit board 132.

In some embodiments, the upper surface 132a of the second circuit board 132 has multiple interconnecting members 132c. Here, the second chip 134 may be connected electrically to the interconnecting members 132c.

In some embodiments, the interconnecting member 132c may be a contact point on a conductive circuit (not shown), or a solder pad of the second circuit board 132.

The electronic function module 150 includes a third circuit board 152 and at least one third chip 154.

The third chip 154 is located on an upper surface 152a of the third circuit board 152 and connected electrically to the third circuit board 152.

In some embodiments, when the electronic function module 150 has multiple third chips 154, the third chips 154 may be disposed on the upper surface 152a of the third circuit board 152 in a side-by-side manner or stacking manner. In addition, a part of the third chips 154 may be disposed on the upper surface 152a of the third circuit board 152 in a side-by-side manner, and another part is disposed on the upper surface 152a of the third circuit board 152 in a stacking manner.

In some embodiments, the third chip 154 may be connected electrically to the third circuit board 152 through wire-bonding or flip-chip.

In some embodiments, the upper surface 152a of the third circuit board 152 has multiple interconnecting members (not shown, and a structure thereof is roughly the same as the above description). Here, the third chip 154 may be connected electrically to the interconnecting members.

In some embodiments, the interconnecting member may be a contact point on a conductive circuit or a solder pad of the third circuit board 152.

Here, the second package body 130 and the electronic function module 150 are disposed on the first package body 110 in a side-by-side manner. In other words, the second circuit board 132 and the third circuit board 152 are located on the first sealing compound 116.

In some embodiments, the lower surface 132b of the second circuit board 132 may adjoin (directly contact), the first package body 110. The lower surface 152b of the third circuit board 152 may adjoin (directly contact), the first package body 110.

The second connecting conductors 140 are disposed between the first package body 110 and the second package body 130. The second connecting conductors 140 are located between the first circuit board 112 and the second circuit board 132, and two ends of the second connecting conductors 140 are respectively connected electrically to the upper surface 112a of the first circuit board 112 and the lower surface 132b of the second circuit board 132, so that the first circuit board 112 and the second circuit board 132 are conducted electrically through the second connecting conductors 140. Therefore, the electronic components disposed in the second package body 130 may be conducted electrically to the first connecting conductors 120 through the second circuit board 132 and the first circuit board 112.

In some embodiments, the second connecting conductors 140 penetrate the first sealing compound 116 and are connected electrically to the first circuit board 112 and the second circuit board 132.

In some embodiments, the lower surface 132b of the second circuit board 132 may have multiple solder pads 132d. The second connecting conductors 140 are physically connected to the solder pads 132d of the second circuit board 132, and the solder pads 132d are connected electrically to the conductive circuit of the second circuit board 132. The second chip 134 on the upper surface 132a may therefore be connected electrically to the second connecting conductors 140 on the lower surface 132b through the conductive circuit and the solder pads 132d.

In some embodiments, the upper surface 112a of the first circuit board 112 may have multiple solder pads 112e. The other end of the second connecting conductors 140 opposite to the second circuit board 132 is physically connected to the solder pads 112e of the first circuit board 112. In addition, the solder pads 112e are connected electrically to the conductive circuit of the first circuit board 112. The second chip 134 may therefore be conducted electrically to the first connecting conductors 120 on the lower surface 112b of the first circuit board 112 through the conductive circuit and the solder pads 132d of the second circuit board 132, the second connecting conductors 140, and the conductive circuit and the solder pads 112e of the first circuit board 112.

The third connecting conductors 160 are disposed between the first package body 110 and the electronic function module 150. The third connecting conductors 160 are located between the first circuit board 112 and the third circuit board 152, and two ends of the third connecting conductors 160 are respectively connected electrically to the upper surface 112a of the first circuit board 112 and the lower surface 152b of the third circuit board 152, so that the first circuit board 112 and the third circuit board 152 are conducted electrically through the third connecting conductors 160. The electronic components disposed in the electronic function module 150 may therefore be conducted electrically to the first connecting conductors 120 through the third circuit board 152 and the first circuit board 112.

In some embodiments, the third connecting conductors 160 penetrate the first sealing compound 116 and are connected electrically to the first circuit board 112 and the third circuit board 152.

In some embodiments, the lower surface 152b of the third circuit board 152 may have multiple solder pads 152d. The third connecting conductors 160 are physically connected to the solder pads 152d of the third circuit board 152, and the solder pads 152d are connected electrically to the conductive circuit of the third circuit board 152. The third chip 154 on the upper surface 152a may therefore be connected electrically to the third connecting conductors 160 on the lower surface 152b through the conductive circuit and the solder pads 152d.

In some embodiments, the upper surface 112a of the first circuit board 112 may have multiple solder pads 112e. The other end of the third connecting conductors 160 opposite to the third circuit board 152 is physically connected to the solder pads 112e of the first circuit board 112. In addition, the solder pads 112d are connected electrically to the conductive circuit of the first circuit board 112. The third chip 154 may therefore be conducted electrically to the first connecting conductors 120 on the lower surface 112b of the first circuit board 112 through the conductive circuit and the solder pads 152d of the third circuit board 152, the third connecting conductors 160, and the conductive circuit and the solder pads 112e of the first circuit board 112.

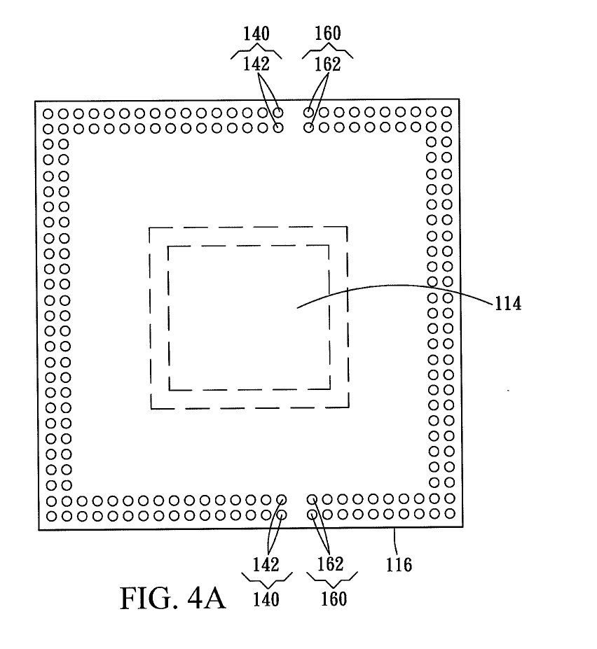

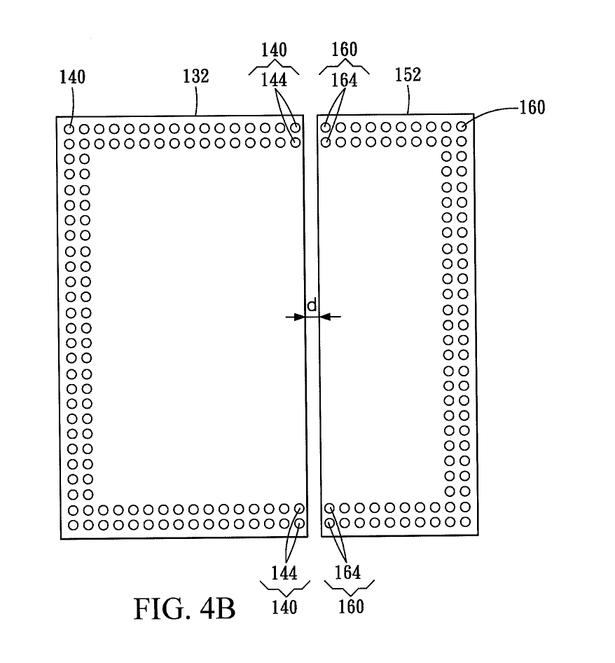

FIG. 4A is a top view along a tangential line B-B′ in FIG. 3, and FIG. 4B is a bottom view along a tangential line C-C′ in FIG. 3. Please refer to FIG. 3 in combination with FIG. 4A and FIG. 4B, in which the second connecting conductors 140 and the third connecting conductors 160 are arranged around the first chip 114.

In some embodiments, the second connecting conductors 140 and the third connecting conductors 160 may be arranged along an edge of the first circuit board 112.

In some embodiments, the second connecting conductors 140 are arranged into a shape of letter C with an opening toward the third connecting conductors 160. The third connecting conductors 160 are arranged into a shape of letter C with an opening toward the second connecting conductors 140.

In some embodiments, Please refer to FIG. 3, FIG. 4A, and FIG. 4B, the second connecting conductor 140 may include two solder balls 142 and 144. The solder ball 142 may be formed on the solder pad 112e of the first circuit board 112 through a solder ball implanting technology, and the solder ball 144 may be formed on the solder pad 132d of the second circuit board 132 through the solder ball implanting technology. In addition, the solder balls 142 and 144 are connected electrically. In other words, two opposite sides of the solder ball 142 are respectively physically connected to the upper surface 112a (the solder pad 112e), of the first circuit board 112 and the solder ball 144, and two opposite sides of the solder ball 144 are respectively physically connected to the solder ball 142 and the lower surface 132b (the solder pad 132d), of the second circuit board 132.

In some embodiments, with reference to FIG. 3, FIG. 4A, and FIG. 4B, the third connecting conductor 160 may include two solder balls 162 and 164. The solder ball 162 may be formed on the solder pad 112e of the first circuit board 112 through the solder ball implanting technology, and the solder ball 164 may be formed on the solder pad 152d of the third circuit board 152 through the solder ball implanting technology. In addition, the solder balls 162 and 164 are connected electrically. In other words, two opposite sides of the solder ball 162 are respectively physically connected to the upper surface 112a (the solder pad 112e). of the first circuit board 112 and the solder ball 164, and two opposite sides of the solder ball 164 are respectively physically connected to the solder ball 162 and the lower surface 152b (the solder pad 152d), of the third circuit board 152.

Furthermore, Please refer to FIG. 2, the two solder balls 142 and 144 or the two solder balls 162 and 164 in the same through hole of the first sealing compound 116 may be in fusion splice through thermal processing, so as to ensure electric conductivity between the two solder balls 142 and 144 or the two solder balls 162 and 164.

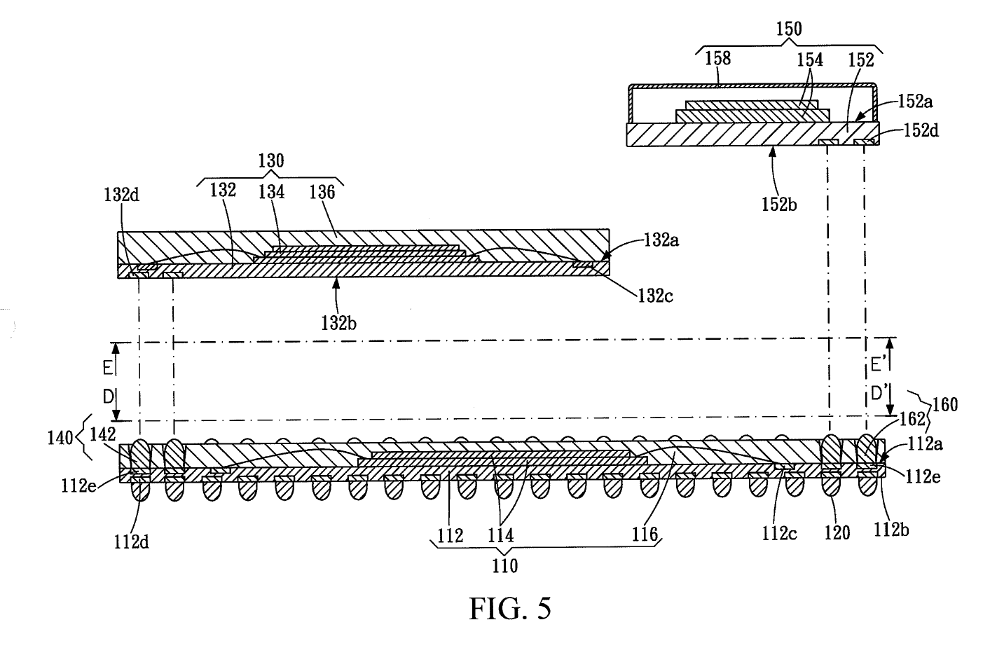

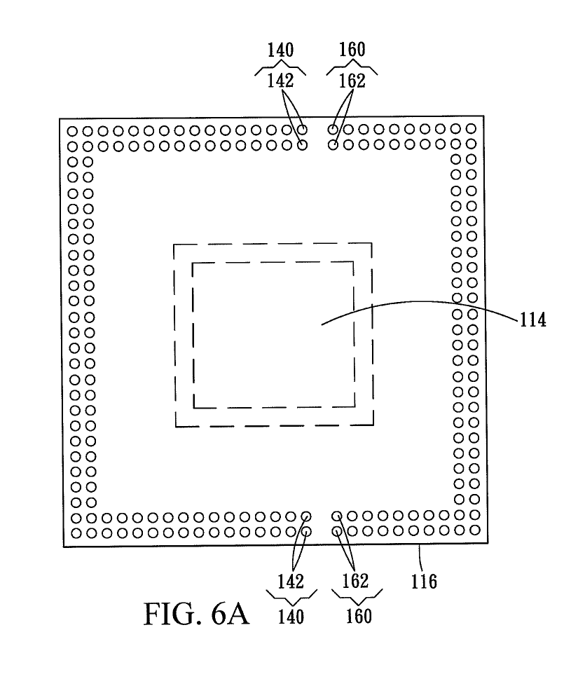

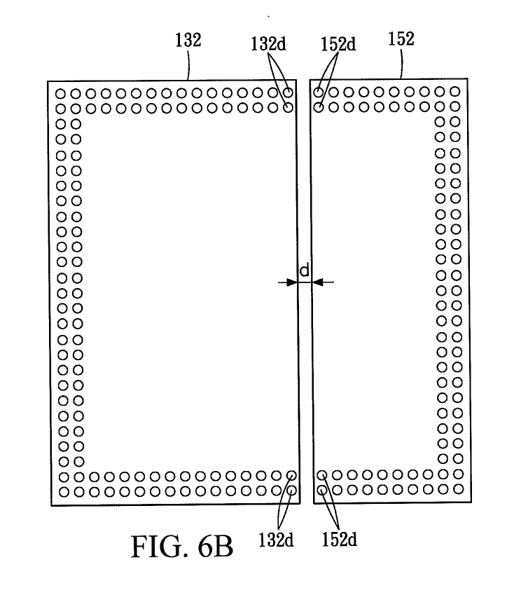

FIG. 5 is an exploded view of a section structure of FIG. 2 according to another embodiment, FIG. 6A is a top view along a tangential line D-D′ in FIG. 5, and FIG. 6B is a bottom view along a tangential line E-E′ in FIG. 5.

In some embodiments, with reference to FIG. 5, FIG. 6A, and FIG. 6B, the second connecting conductor 140 may be a solder ball 142 formed on the solder pad 112e of the first circuit board 112 through the solder ball implanting technology. The other side of the solder ball 142 opposite to the first circuit board 112 is connected electrically to the solder pad 132d of the second circuit board 132. A height of the solder ball 142 is slightly greater than that of the first sealing compound 116. In other words, a top portion of the solder ball 142 protrudes from an upper surface of the first sealing compound 116, so that the solder ball 142 is physically connected to the second circuit board 132.

In some embodiments, with reference to FIG. 5, FIG. 6A, and FIG. 6B, the third connecting conductor 160 may be a solder ball 162 formed on the solder pad 112e of the first circuit board 112 through the solder ball implanting technology. The other side of the solder ball 162 opposite to the first circuit board 112 is connected electrically to the solder pad 152d of the third circuit board 152. A height of the solder ball 162 is slightly greater than that of the first sealing compound 116. In other words, a top portion of the solder ball 162 protrudes from the upper surface of the first sealing compound 116, so that the solder ball 162 is physically connected to the third circuit board 152.

Furthermore, with reference to FIG. 2, the solder ball 142 may be in fusion splice with the solder pad 132d of the second circuit board 132 through thermal processing, so as to ensure electric conductivity between the solder ball 142 and the second circuit board 132. In the same manner, the solder ball 162 may be in fusion splice with the solder pad 132d of the second circuit board 152 through thermal processing, so as to ensure electric conductivity between the solder ball 142 and the third circuit board 152.

Here, the electronic function of the second package body 130 is different from the electronic function of the electronic function module 150. In other words, the second package body 130 may be another type of electronic function module with the electronic function different from that of the electronic function module 150.

In some embodiments, the electronic function module 150 may be a wireless communication module, and the second package body 130 may be a memory module.

In some embodiments, the electronic function module 150 (the third package body), may have one or more than two wireless communication technologies. In other words, the electronic function module 150 may have multiple third chips 154, and the third chips 154 are respectively used to implement different wireless communication technologies.

In some embodiment, the third chip 154 may be a Bluetooth chip, a Wireless Fidelity (WiFi) chip, or a combination thereof.

In some embodiments, the second package body 130 may have one or more than two memory technologies. The memory technologies may be a NAND flash, Double Data Rate Synchronous Dynamic Random Access Memory (DDR SDRAM), DDR2 SDRAM, and DDR3 SDRAM.

In some embodiments, the first package body 112 may be an operation module. The first chip 114 may be a master chip. The master chip may be, for example, a Central Processing Unit (CPU).

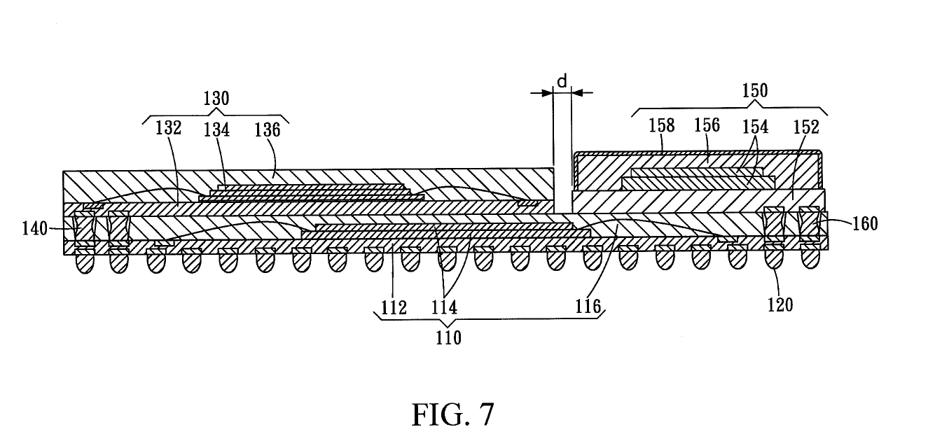

Please refer to FIG. 1, FIG. 2, FIG. 3, and FIG. 5, in which when the electronic function module 150 is a wireless communication module, an electromagnetic shielding case 158 may be disposed, and the electromagnetic shielding case 158 may case an outside of the third chip 154, namely casing all the third chips 154, so as to prevent a radio frequency signal from interfering running of electronic functions of other package bodies (for example, the second package body 130), namely preventing interference on running of other electronic function modules. FIG. 7 is a schematic view of a section structure along a tangential line A-A′ in FIG. 1 according to another embodiment.

Please refer to FIG. 1 and FIG. 7, in which the electronic function module 150 may also be a third package body (150), and the third package body (150) may further include a third sealing compound 156.

The third sealing compound is located on the upper surface 152a of the third circuit board 152. The third sealing compound 156 envelopes the third chip 154, so as to fix the third chip 154 on the third circuit board 152. In other words, the third sealing compound 156 may cover the third chip 154 and the third circuit board 152, so as to wrap the third chip 154 on the third circuit board 152.

In some embodiments, the third package body (150) may be a wireless communication module, and the second package body 130 may be a memory module.

When the third package body (150) is a wireless communication module, an electromagnetic shielding case 158 may be disposed, and the electromagnetic shielding case 158 cases an outside of the third sealing compound 156, namely casing all the third chips 154, so as to prevent a radio frequency signal from interfering running of other electronic functions in the package body, namely preventing interference on running of other electronic function modules.

The electromagnetic shielding case 158 may be a metal roof cover made of one or more pieces of metal sheets.

In some embodiments, when the metal roof cover cases an outside of the third sealing compound 156, the metal roof cover may directly contact the third sealing compound 156, so as to be used as a heat dissipation medium of the third package body (150) at the same time.

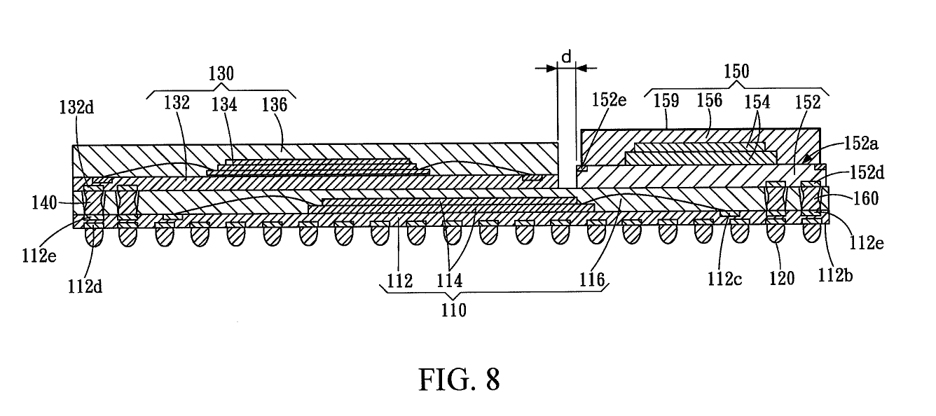

FIG. 8 is a schematic view of a section structure along a tangential line A-A′ in FIG. 1 according to further another embodiment.

Please refer to FIG. 8, in which in some embodiments, a metal coating film 159 may be directly formed on an external surface of the third sealing compound 156, so as to provide electromagnetic shielding and heat dissipation functions of the third package body (150) at the same time.

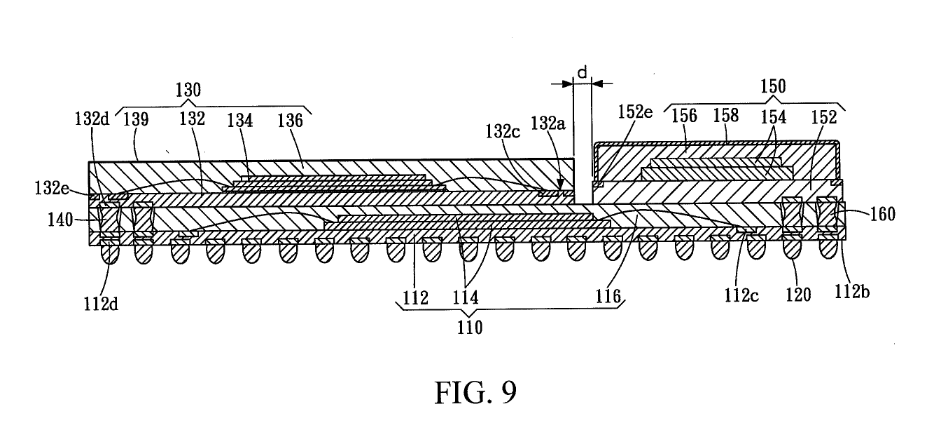

FIG. 9 is a schematic view of a section structure along a tangential line A-A′ in FIG. 1 according to still another embodiment.

Please refer to FIG. 8 and FIG. 9, in which in some embodiments, the upper surface 152a of the third circuit board 152 may have at least one interconnecting member 152e.

The interconnecting member 152e is disposed corresponding to the metal coating film 159 (or the electromagnetic shielding case 158), and is thermal-conductively connected to the metal coating film 159 (or the electromagnetic shielding case 158).

Furthermore, the interconnecting member 152e is further conducted electrically to a connecting conductor with a grounding property in the third connecting conductors 160 through the conductive circuit and the solder pad 152d of the third circuit board 152, and then is conducted electrically to a connecting conductor with a grounding property in the first connecting conductors 120 through the first circuit board 112 (the solder pads 112d, 112e and the conductive circuit), so that heat generated by the third package body (150) may be conducted to grounding of an electronic system applying the stacking-type semiconductor package structure through the metal coating film 159 (or the electromagnetic shielding case 158), the third circuit board 152, the third connecting conductors 160, the first circuit board 112, and the first connecting conductors 120, thereby further improving a heat dissipation effect of the third package body (150).

In some embodiments, the interconnecting member 152e is of a metal material. The interconnecting member 152e may be, for example, a solder pad or a contact point of the conductive circuit.

Please refer to FIG. 9, in which in some embodiments, an external surface of the second sealing compound 136 may be electroplated with a metal coating film 139, so as to be used as a heat dissipation medium of the second package body 130.

In some embodiments, the upper surface 132a of the second circuit board 132 may be disposed with at least one interconnecting member 132e.

The interconnecting member 132e is disposed corresponding to the metal coating film 139, and is thermal-conductively connected to the metal coating film 139.

Furthermore, the interconnecting member 132e is further conducted electrically to a connecting conductor with a grounding property in the second connecting conductors 140 through the conductive circuit and the solder pad 132d of the second circuit board 132, and then is conducted electrically to a connecting conductor with a grounding property in the first connecting conductors 120 through the first circuit board 112 (the solder pads 112d, 112e and the conductive circuit), so that heat generated by the second package body 130 may be conducted to grounding of an electronic system applying the stacking-type semiconductor package structure through the metal coating film 139, the second circuit board 132, the second connecting conductors 140, the first circuit board 112, and the first connecting conductors 120, thereby further improving a heat dissipation effect of the second package body 130.

In some embodiments, the interconnecting member 152e is of a metal material. The interconnecting member 152e may be, for example, a solder pad or a contact point of the conductive circuit.

In some embodiments, the second circuit board 132 and the third circuit board 152 may have different thicknesses. Here, the first circuit board 112 may have the same thickness as the second circuit board 132 or the third circuit board 152. Furthermore, the first circuit board 112, the second circuit board 132, and the third circuit board 152 may have different thicknesses.

In some embodiments, the second circuit board 132 and the third circuit board 152 may be multi-layer substrates with different number of layers. Here, the first circuit board 112 may be a multi-layer substrate with the same number of layers as the second circuit board 132 or the third circuit board 152.

In some embodiments, the substrates of the first circuit board 112, the second circuit board 132, and the third circuit board 152 may have different number of layers.

In some embodiments, the second package body 130 and the electronic function module 150 (the third package body), are spaced with each other and disposed on the first package body 110, so as to increase a heat dissipation area for thermal energy generated due to an electric heat difference among different electronic function modules. In other words, an interval d exists between the second package body 130 and the electronic function module 150 (the third package body).

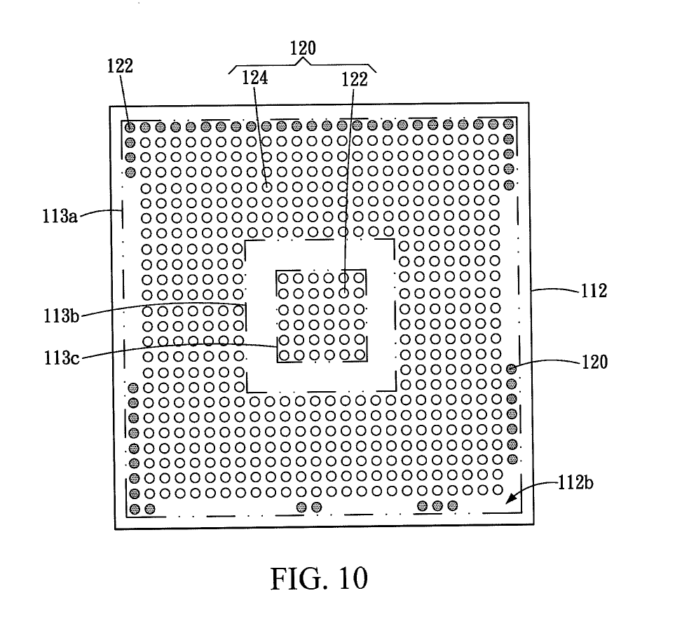

FIG. 10 is a bottom view of a stacking-type semiconductor package structure according to an embodiment of the present invention.

Please refer to FIG. 10, in which in some embodiments, the lower surface 112b of the first circuit board 112 may include a first region 113a, a second region 113b, and a third region 113c.

The second region 113b is located between the first region 113a and the third region 113c, so as to space the first region 113a and the third region 113c.

The first connecting conductor 120 may include multiple grounding conductors 122 and multiple power source conductors 124. Here, the grounding conductor 122 is referred to by a grounding property thereof, that is, the grounding conductor 122 is a connecting conductor connected electrically to the grounding of the electronic system applying the stacking-type semiconductor package structure. The power source conductor 124 is referred to by a power source property thereof, that is, the power source conductor 124 is a connecting conductor connected electrically to a power source of the electronic system.

The second region 113b is not disposed with the first connecting conductors 120.

In some embodiments, the second region 113b may be disposed with at least one passive element, and the passive elements are connected electrically to the first circuit board 112.

The third region 113c is fully disposed with the grounding conductors 122.

The power source conductors 124 are all disposed in the first region 113a.

In some embodiments, a minority of the grounding conductors 122 may also be disposed in the first region 113a.

In some embodiments, the grounding conductors 122 in the first region 113a may be disposed at an outmost circle (such as shadowed connecting conductors shown in the figure), in correspondence to the second connecting conductors 140 or the third connecting conductors 160, so that the second connecting conductors 140 and the third connecting conductors 160 with the grounding property may easily penetrate the conductive circuit of the first circuit board 112 and be connected electrically to the grounding conductors 122 in the first connecting conductors 120.

In some embodiments, the second region 113b surrounds the third region 113c. In addition, the first region 113a also surrounds the second region 113b.

In some embodiments, the third region 113c is rectangular, and the grounding conductors 122 configured in the third region 113c are arranged in matrix.

In some embodiments, the first connecting conductor 120 is a solder ball formed on the lower surface 112b of the first circuit board 112 through the solder ball implanting technology.

In conclusion, the stacking-type semiconductor package structure according to the present invention can combine at least three electronic function modules, and the electronic function modules have at least two different electronic functions. Furthermore, the electronic function modules may be assembled separately, and then the electronic function modules are assembled, so as to increase a yield.

In some embodiments, the stacking-type semiconductor package structure according to the present invention may use gap disposition and/or configuration of grounding conductors between electronic function modules with different electronic functions, so as to improve a heat dissipation effect.

In some embodiments, the stacking-type semiconductor package structure according to the present invention may use an electromagnetic shielding case to shield electromagnetic waves generated by a wireless communication module, so as to prevent interference on other electronic function modules.

While the present invention has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

1. A stacking-type semiconductor package structure, comprising:
a first package body, comprising:
a first circuit board;
at least one first chip, located on an upper surface of the first circuit board and connected electrically to the first circuit board; and
a first sealing compound, located on the upper surface of the first circuit board to envelope the at least one first chip;
a plurality of first connecting conductors, located on a lower surface of the first circuit board and connected electrically to the first circuit board;
a second package body, comprising:
a second circuit board, located on the first sealing compound;
at least one second chip, located on an upper surface of the second circuit board and connected electrically to the second circuit board; and
a second sealing compound, located on the upper surface of the second circuit board to envelope the at least one second chip;
a plurality of second connecting conductors, located between the first circuit board and the second circuit board, and connected electrically to the first circuit board and the second circuit board;
an electronic function module, comprising:
a third circuit board, located on the first sealing compound; and
at least one third chip, located on an upper surface of the third circuit board, and connected electrically to the third circuit board; and
a plurality of third connecting conductors, located between the first circuit board and the third circuit board, and connected electrically to the first circuit board and the third circuit board;
wherein the second package body has an electronic function different from that of the electronic function module.

2. The stacking-type semiconductor package structure according to claim 1, wherein the electronic function module is a wireless communication module, and the second package body is a memory module.

3. The stacking-type semiconductor package structure according to claim 2, the electronic function module further comprises: an electromagnetic shielding case, casing an outside of the at least one third chip.

4. The stacking-type semiconductor package structure according to claim 1, wherein the electronic function module is a third package body, and the third package body further comprises a third sealing compound located on the upper surface of the third circuit board to envelope the at least one third chip.

5. The stacking-type semiconductor package structure according to claim 4, wherein the electronic function module further comprises: an electromagnetic shielding case, casing an outside of the third sealing compound.

6. The stacking-type semiconductor package structure according to claim 5, wherein the electromagnetic shielding case directly contacts the third sealing compound.

7. The stacking-type semiconductor package structure according to claim 6, wherein the electromagnetic shielding case is thermal-conductively connected to the third circuit board.

8. The stacking-type semiconductor package structure according to claim 4, wherein the electronic function module further comprises: a metal coating film, formed on an external surface of the third sealing compound.

9. The stacking-type semiconductor package structure according to claim 8, wherein the metal coating film is thermal-conductively connected to the third circuit board.

10. The stacking-type semiconductor package structure according to claim 1, wherein the second package body further comprises: a metal coating film, formed on an external surface of the second sealing compound.

11. The stacking-type semiconductor package structure according to claim 10, wherein the metal coating film is thermal-conductively connected to the second circuit board.

12. The stacking-type semiconductor package structure according to claim 1, wherein the second package body and the electronic function module are spaced with each other and disposed on the first package body.

13. The stacking-type semiconductor package structure according to claim 1, wherein the second connecting conductors and the third connecting conductors are arranged around the at least one first chip.

14. The tacking-type semiconductor package structure according to claim 1, wherein the second connecting conductors penetrate the first sealing compound and are connected electrically to the first circuit board and the second circuit board, and the third connecting conductors penetrate the first sealing compound and are connected electrically to the first circuit board and the third circuit board.

15. The tacking-type semiconductor package structure according to claim 14, wherein each of the second connecting conductors is formed by two physically connected solder balls, and two opposite sides of the two solder balls are respectively physically connected to the upper surface of the first circuit board and the lower surface of the second circuit board.

16. The tacking-type semiconductor package structure according to claim 14, wherein each of the third connecting conductors is formed by two physically connected solder balls, and two opposite sides of the two solder balls are respectively physically connected to the upper surface of the first circuit board and the lower surface of the third circuit board.

17. The tacking-type semiconductor package structure according to claim 1, wherein each of the first connecting conductors is a solder ball, and the solder ball is physically connected to the lower surface of the first circuit board.

18. The stacking-type semiconductor package structure according to claim 2, wherein the second package body and the electronic function module are spaced with each other and disposed on the first package body.

19. The stacking-type semiconductor package structure according to claim 3, wherein the second package body and the electronic function module are spaced with each other and disposed on the first package body.

20. The stacking-type semiconductor package structure according to claim 4, wherein the second package body and the electronic function module are spaced with each other and disposed on the first package body.

21. The stacking-type semiconductor package structure according to claim 5, wherein the second package body and the electronic function module are spaced with each other and disposed on the first package body.

22. The stacking-type semiconductor package structure according to claim 6, wherein the second package body and the electronic function module are spaced with each other and disposed on the first package body.

23. The stacking-type semiconductor package structure according to claim 7, wherein the second package body and the electronic function module are spaced with each other and disposed on the first package body.

24. The stacking-type semiconductor package structure according to claim 8, wherein the second package body and the electronic function module are spaced with each other and disposed on the first package body.

25. The stacking-type semiconductor package structure according to claim 9, wherein the second package body and the electronic function module are spaced with each other and disposed on the first package body.

26. The stacking-type semiconductor package structure according to claim 10, wherein the second package body and the electronic function module are spaced with each other and disposed on the first package body.

27. The stacking-type semiconductor package structure according to claim 11, wherein the second package body and the electronic function module are spaced with each other and disposed on-the first package body.

28. The tacking-type semiconductor package structure according to claim 13, wherein the second connecting conductors penetrate the first sealing compound and are connected electrically to the first circuit board and the second circuit board, and the third connecting conductors penetrate the first sealing compound and are connected electrically to the first circuit board and the third circuit board.

29. The tacking-type semiconductor package structure according to claim 28, wherein each of the second connecting conductors is formed by two physically connected solder balls, and two opposite sides of the two solder balls are respectively physically connected to the upper surface of the first circuit board and the lower surface of the second circuit board.

30. The tacking-type semiconductor package structure according to claim 28, wherein each of the third connecting conductors is formed by two physically connected solder balls, and two opposite sides of the two solder balls are respectively physically connected to the upper surface of the first circuit board and the lower surface of the third circuit board.
